(19) United States
(12) Patent Application Publication
(10) Pub. No.: US 2023/0238249 A1
(43) Pub. Date: Jul. 27, 2023

(54) METHOD FOR MANUFACTURING SEMICONDUCTOR STRUCTURE AND SEMICONDUCTOR STRUCTURE

(71) Applicant: CHANGXIN MEMORY TECHNOLOGIES, INC., Hefei City, Anhui (CN)

(72) Inventors: Bo SHAO, Hefei City, Anhui (CN); Xinran LIU, Hefei City, Anhui (CN); Chunyang WANG, Hefei City, Anhui (CN); Yule SUN, Hefei City, Anhui (CN); Zhenxing LI, Hefei City, Anhui (CN)

(73) Assignee: CHANGXIN MEMORY TECHNOLOGIES, INC., Hefei City, Anhui (CN)

(21) Appl. No.: 17/593,851

(22) PCT Filed: Jun. 30, 2021
(86) PCT No.: PCT/CN2021/103733

§ 371 Date: Sep. 26, 2021

(30) Foreign Application Priority Data
Mar. 12, 2021 (CN) 202110269758.5

(51) Int. Cl. H01L 21/311; H01L 21/3105

(52) U.S. Cl. CPC H01L 21/31144; H01L 21/31053; H01L 21/31116

(57) ABSTRACT

In the method for manufacturing a semiconductor structure, a film structure is formed on a substrate, a pattern transfer layer is formed on the film structure, a plurality of holes are defined on the pattern transfer layer, and the pattern transfer layer is flattened; the film structure is etched through the holes to form capacitor holes in the film structure.

### CROSS-REFERENCE TO RELATED APPLICATIONS

The present disclosure claims priority to Chinese Patent Application No. 202110269758.5, entitled “METHOD FOR MANUFACTURING SEMICONDUCTOR STRUCTURE AND SEMICONDUCTOR STRUCTURE”, filed to the CNIPA on Mar. 12, 2021, which is incorporated herein by reference in its entirety.

### TECHNICAL FIELD

Embodiments of the present application relate to the field of semiconductor manufacturing technology, and in particular, to a method for manufacturing a semiconductor structure and a semiconductor structure.

### BACKGROUND

With the gradual development of storage device technology, Dynamic Random-Access Memory (DRAM) is gradually applied in various electronic devices due to its relatively high density and relatively fast read and write speed. The DRAM includes a capacitor structure and a transistor structure, the capacitor structure is connected to the transistor structure, and data stored in the capacitor structure can be read through the transistor structure.

In the related technology, the capacitor structure includes a substrate and a dielectric layer disposed on the substrate, the dielectric layer is provided with a capacitor hole, and a capacitor tube is disposed in the capacitor hole. During manufacturing, the dielectric layer is first formed on the substrate, and a pattern transfer layer is formed on the dielectric layer. The pattern transfer layer has a hole, and the dielectric layer is etched along the hole by dry etching to form the capacitor hole in the dielectric layer.

However, when the pattern transfer layer is formed, the top surface of the pattern transfer layer away from the substrate is relatively rough. During the etching of the dielectric layer, the rough top surface is likely to cause ion scattering, resulting in poor dimensional accuracy of the capacitor hole formed, which affects the performance of the capacitor structure.

### SUMMARY

In the first aspect, an embodiment of the present application provides a method for manufacturing a semiconductor structure, including:

providing a substrate;

forming a film structure on the substrate, the film structure including a dielectric layer;

forming a pattern transfer layer on the film structure, a plurality of holes being defined on the pattern transfer layer;

flattening a top surface of the pattern transfer layer away from the substrate; and

etching the film structure through the holes to form capacitor holes in the film structure.

In the second aspect, an embodiment of the present application further provides a semiconductor structure, which is manufactured by the above-mentioned method for manufacturing the semiconductor structure.

In combination with the above technical solutions, in the method for manufacturing a semiconductor structure and a semiconductor structure provided by the embodiments of the present application, a film structure is formed on a substrate, the film structure includes a dielectric layer, a pattern transfer layer is formed on the film structure, a plurality of holes are defined on the pattern transfer layer, and the pattern transfer layer is flattened; the film structure is etched through the holes to form capacitor holes in the film structure; before the capacitor holes are formed, the top surface of the pattern transfer layer is flattened, and the flat top surface of the pattern transfer layer can avoid ion scattering during the etching, thereby avoiding bulging on side walls of the formed capacitor holes or tilting of the capacitor holes, improving the dimensional accuracy of the capacitor holes and improving the performance of capacitor structure.

### BRIEF DESCRIPTION OF THE DRAWINGS

To describe the technical solutions in the embodiments of the present application or in the prior art more clearly, the following briefly introduces the accompanying drawings required for describing the embodiments or the prior art. Apparently, the accompanying drawings in the following description show some embodiments of the present application, and those of ordinary skill in the art may derive other drawings from these accompanying drawings without any creative efforts.

FIG. 1 is a flowchart of a method for manufacturing a semiconductor structure according to an embodiment of the present application;

FIG. 2 is a schematic structure diagram after a second pattern transfer layer is formed in the method for manufacturing a semiconductor structure according to an embodiment of the present application;

FIG. 3 is a partial enlarged view of A in FIG. 2;

FIG. 4 is a schematic structure diagram after holes are formed in the method for manufacturing a semiconductor structure according to an embodiment of the present application;

FIG. 5 is a schematic structure diagram after the top surface of the pattern transfer layer is flattened in the method for manufacturing a semiconductor structure according to an embodiment of the present application;

FIG. 6 is a schematic structure diagram after capacitor holes are formed in the method for manufacturing a semiconductor structure according to an embodiment of the present application.

Reference numerals:

| | |
|---|---|
| 10: substrate; | 101: conduction region; |
| 20: film structure; | 201: top film; |
| 202: dielectric layer; | 203: first dielectric layer; |
| 204: middle film; | 205: second dielectric layer; |
| 206: capacitor hole; | 30: first pattern transfer layer; |
| 301: hole; | 302: depression; |
| 303: protrusion; | 40: second pattern transfer layer; |
| 401: hole pattern. | |

### DETAILED DESCRIPTION

In order to make the objectives, technical solutions and advantages of the embodiments of the present application clearer, the technical solutions in the embodiments of the present application will be described clearly and completely below in conjunction with the accompanying drawings in the embodiments of the present application. Apparently, the described embodiments are part of the embodiments of the present application, not all of them. All other embodiments obtained by those of ordinary skill in the art without creative efforts based on the embodiments of the present application shall fall within the protection scope of the present application.

Dynamic Random-Access Memory (DRAM) generally includes a capacitor structure and a transistor structure, the capacitor structure is connected to the transistor structure, and data stored in the capacitor structure can be read through the transistor structure.

In the related technology, the capacitor structure includes a substrate and a dielectric layer disposed on the substrate, the dielectric layer is provided with a capacitor hole, and a capacitor tube is disposed in the capacitor hole. During manufacturing, the dielectric layer is first formed on the substrate, and a pattern transfer layer is formed on the dielectric layer. The pattern transfer layer has a hole, and the dielectric layer is etched along the hole by dry etching to form the capacitor hole in the dielectric layer.

However, when the pattern transfer layer is formed, the top surface of the pattern transfer layer away from the substrate is relatively rough. During the etching of the dielectric layer, the rough top surface is likely to cause ion scattering and bending of the capacitor hole or uneven inner wall of the capacitor hole, resulting in poor dimensional accuracy of the formed capacitor hole, which affects the performance of the capacitor structure.

The embodiments of the present application provide a method for manufacturing a semiconductor structure and a semiconductor structure. After a pattern transfer layer is formed, the top surface of the pattern transfer layer away from the substrate is flattened, thereby avoiding ion scattering during etching, improving the dimensional accuracy of formed capacitor holes, and improving the performance of capacitor structure.

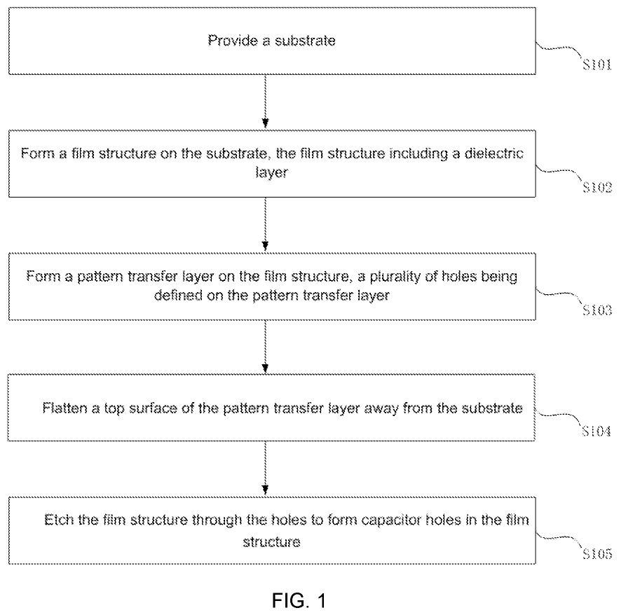

Referring to FIG. 1, the method for manufacturing a semiconductor structure provided in this embodiment includes:

S101: a substrate is provided.

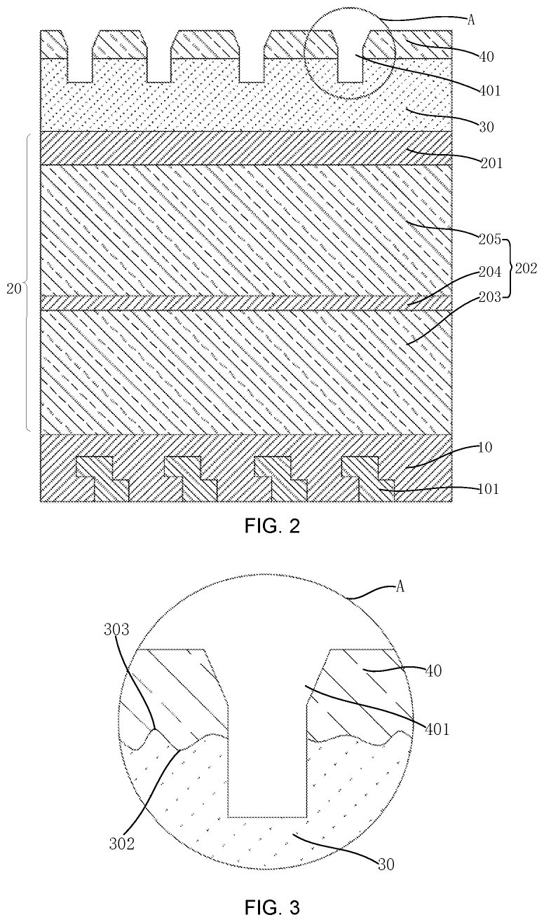

Referring to FIG. 2, the substrate 10 is used as the basis of the semiconductor structure to support other films formed in subsequent steps. The material of the substrate 10 may include silicon nitride or the like, and the material of the substrate 10 is not limited in this embodiment.

After the substrate 10 is formed, the method for manufacturing a semiconductor structure provided in this embodiment further includes:

S102: a film structure is formed on the substrate, the film structure including a dielectric layer.

Continuing to refer to FIG. 2, exemplarily, the specific step of manufacturing the film structure 20 may include: sequentially stacking a dielectric layer 202 and a top film 201 on the substrate 10. The top film 201 is located on the side of the dielectric layer 202 away from the substrate 10, and the material of the top film 201 may include titanium nitride or the like.

Further, the dielectric layer 202 may include a first dielectric layer 203, a middle film 204 and a second dielectric layer 205 sequentially stacked on the substrate 10. That is, the middle film 204 is located between the first dielectric layer 203 and the second dielectric layer 205, the first dielectric layer 203 is disposed close to the substrate 10, and the second dielectric layer 205 is disposed close to the top film 201.

The material of the first dielectric layer 203 may include an oxide such as silicon oxide, the material of the middle film 204 may include titanium nitride or the like, and the material of the second dielectric layer 205 may also include an oxide such as silicon oxide.

In some embodiments, a bottom surface of the first dielectric layer 203 is bonded to the substrate 10, a top surface of the first dielectric layer 203 is bonded to a bottom surface of the middle film 204, a top surface of the middle film 204 is bonded to a bottom surface of the second dielectric layer 205, and a top surface of the second dielectric layer 205 is bonded to the top film 201, so that the first dielectric layer 203, the middle film 204, the second dielectric layer 205, and the top film 201 constitute the film structure 20.

In the foregoing implementation, the materials of the middle film 204 and the top film 201 may be the same to reduce the types of materials constituting the film structure 20, so as to facilitate the manufacturing of the film structure 20. Exemplarily, both the middle film 204 and the top film 201 may be titanium nitride layers made of titanium nitride.

Further, the materials of the first dielectric layer 203 and the second dielectric layer 205 may be the same to further reduce the types of materials constituting the film structure 20, so as to facilitate the manufacturing of the film structure 20. Exemplarily, both the first dielectric layer 203 and the second dielectric layer 205 may be oxide layers made of an oxide, such as silicon oxide.

After the film structure 20 is formed, the method for manufacturing a semiconductor structure provided in this embodiment further includes:

S103: a pattern transfer layer is formed on the film structure, a plurality of holes being defined on the pattern transfer layer.

Referring to FIG. 3, in this embodiment, the plurality of holes 301 defined on the pattern transfer layer may be formed by etching; for example, a photoresist layer may be first formed on the pattern transfer layer, and the photoresist layer is masked, exposed and the like to form an etching pattern on the photoresist layer; and then the pattern transfer layer is etched using the photoresist layer as a mask to form the holes 301 on the pattern transfer layer. Of course, the holes 301 in this embodiment may also be formed in other ways, which is not limited in this embodiment.

After the pattern transfer layer is formed, the method for manufacturing a semiconductor structure provided in this embodiment further includes:

S104: a top surface of the pattern transfer layer away from the substrate is flattened.

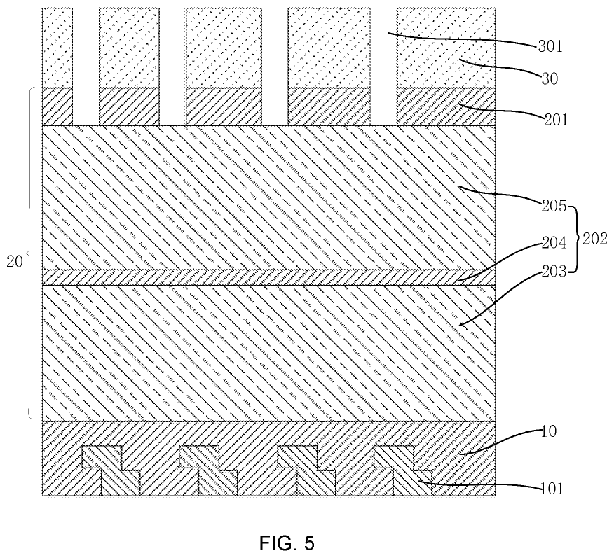

As shown in FIG. 5, the top surface of the pattern transfer layer away from the substrate 10 can become flat by the flattening to facilitate subsequent processes. Exemplarily, the top surface of the pattern transfer layer away from the substrate 10 may be processed by a chemical mechanical polishing (CMP) method, so that the top surface of the pattern transfer layer is relatively flat. Of course, the flattening of the pattern transfer layer in this embodiment is not limited to chemical mechanical polishing, and other methods may also be used to flatten the pattern transfer layer.

After the pattern transfer layer is flattened, the method for manufacturing a semiconductor structure provided in this embodiment further includes:

S105: the film structure is etched through the holes to form capacitor holes 206 in the film structure.

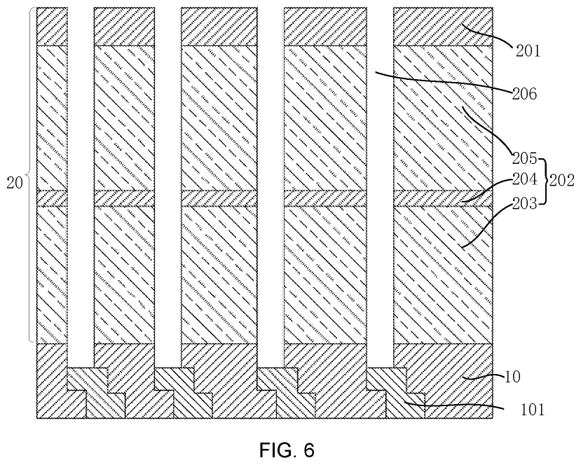

Referring to FIG. 6, the film structure 20 is etched along the holes 301 to form capacitor holes 206, bottoms of the capacitor holes 206 extend toward the substrate 10, and the bottoms of the capacitor holes 206 may be in contact with the substrate 10. Further, when the substrate 10 is formed, a plurality of conduction regions 101 may be formed on the substrate 10. After the capacitor holes 206 are formed, the bottom of each capacitor hole 206 may extend into the substrate 10 and be bonded with a conduction region 101. In the subsequent process, a capacitor plate is formed in the capacitor hole 206, and the capacitor plate may be connected to the conduction region 101 to form a capacitor structure of a dynamic random-access memory. A transistor structure of the dynamic random-access memory may read data in the capacitor structure or write data into the capacitor structure by connecting the conduction region 101 with the corresponding capacitor plate in the capacitor structure.

In this embodiment, the film structure 20 may be etched through the holes 301 by dry etching to form capacitor holes 206 in the film structure 20. The capacitor holes 206 are formed by dry etching, which simplifies the manufacturing difficulty of the capacitor holes 206. As shown in FIGS. 3-6, when the first pattern transfer layer 30 is formed, protrusions 303 and depressions 302 are easily formed on the top surface of the first pattern transfer layer 30, so that the top surface of the first pattern transfer layer 30 is relatively rough; before the etching, the top surface of the pattern transfer layer is flattened, which enables the top surface of the pattern transfer layer to be relatively flat; compared with the rough top surface, ion scattering occurring on the top surface of the pattern transfer layer may be avoided during dry etching, and then the problems of bulging on side walls of the capacitor holes 206 formed or tilting of the capacitor holes and the like can be avoided, thereby improving the dimensional accuracy of the capacitor holes 206 and improving the performance of capacitor structure. In addition, compared with the rough top surface of the pattern transfer layer, damage to the top surface of the film structure 20 at edges of the capacitor holes 206 due to the ion scattering may also be avoided during the etching, so that the top surface of the film structure 20 away from the substrate 10 is relatively flat, which further improves the performance of the capacitor structure.

In the method for manufacturing a semiconductor structure provided in this embodiment, a film structure 20 is formed on a substrate 10, the film structure 20 includes a dielectric layer 202, a pattern transfer layer is formed on the film structure 20, a plurality of holes 301 are defined on the pattern transfer layer, and the pattern transfer layer is flattened; then the film structure 20 is etched through the holes 301 to form capacitor holes 206 in the film structure 20; before the capacitor holes 206 are formed, the top surface of the pattern transfer layer is flattened, and the flat top surface of the pattern transfer layer can avoid ion scattering during the etching, thereby avoiding bulging on side walls of the formed capacitor holes 206 or tilting of the capacitor holes 206, improving the dimensional accuracy of the capacitor holes 206 and improving the performance of capacitor structure.

Continuing to refer to FIGS. 2 to 4, in the method for manufacturing a semiconductor structure provided by this embodiment, the specific step of forming a pattern transfer layer on the film structure 20, a plurality of holes 301 being defined on the pattern transfer layer includes:

A first pattern transfer layer 30 and a second pattern transfer layer 40 are sequentially stacked on the film structure 20, the second mask layer having hole patterns 401; and then transferring the hole patterns 401 to the first pattern transfer layer 30, to form the holes 301.

The first pattern transfer layer 30 may be a polysilicon layer made of polysilicon, and the second pattern transfer layer 40 may also be an oxide layer made of oxide. This embodiment does not limit the materials of the first pattern transfer layer 30 and the second pattern transfer layer 40.

In this embodiment, sequentially stacking a first pattern transfer layer 30 and a second pattern transfer layer 40 on the film structure 20, the second pattern transfer layer 40 having hole patterns 401 includes: etching the second pattern transfer layer 40, to form preset holes, the preset holes extending into the first pattern transfer layer 30. The preset holes extending into the first pattern transfer layer 30 can reduce the depth requirement for etching the second pattern transfer layer 40, thereby simplifying the difficulty in manufacturing the semiconductor structure.

Exemplarily, after the second pattern transfer layer 40 is formed, a first photoresist layer may be formed on the second pattern transfer layer 40, then the first photoresist layer may be masked, exposed and the like to form first etching patterns on the first photoresist layer, and the second pattern transfer layer 40 is etched using the first photoresist layer as a mask to form the hole patterns 401 composed of the preset holes.

Further, the specific step of transferring the hole patterns 401 to the first pattern transfer layer 30 may include, after the hole patterns 401 are formed on the second pattern transfer layer 40, a second photoresist layer may be formed on the second pattern transfer layer 40, then the second photoresist layer is masked, exposed and the like to form second etching patterns on the second photoresist layer, the projections of the second etching patterns on the substrate 10 may completely overlap the projections of the first etching patterns on the substrate 10, and the substrate 10 is etched using the second photoresist layer as a mask to form the holes 301. Because the projections of the second etching patterns on the substrate 10 completely overlap the projections of the first etching patterns on the substrate 10, the formed holes 301 are opposite to the hole patterns 401, and then the hole patterns 401 are transferred to the first pattern transfer layer 30. Of course, in other implementations, after the hole patterns 401 are formed on the second pattern transfer layer 40, the first pattern transfer layer 30 may be etched to the substrate 10 using the second pattern transfer layer 40 as a mask, or the hole patterns 401 may be transferred to the first pattern transfer layer 30, to form the holes 301.

In this embodiment, transferring the hole patterns 401 to the first pattern transfer layer 30, to form the holes 301 further includes: the holes 301 extending into the film structure 20. This configuration can reduce the depth requirement for etching the first pattern transfer layer 30, thereby simplifying the difficulty in manufacturing the semiconductor structure.

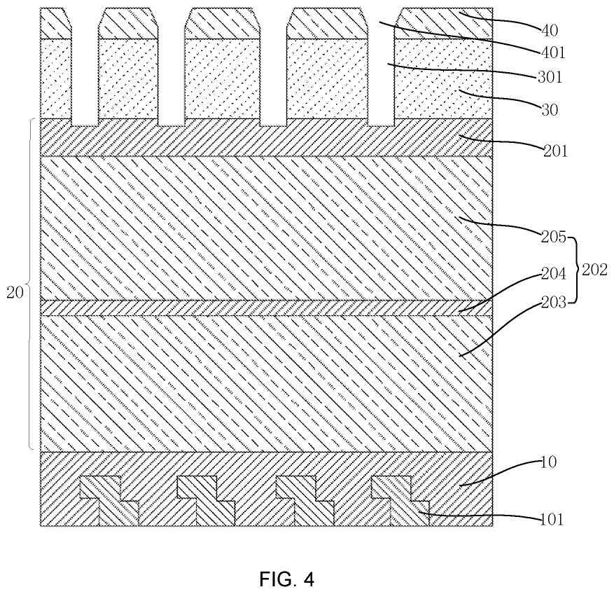

Referring to FIGS. 4 and 5, in the above implementation, the specific step of flattening the top surface of the pattern transfer layer away from the substrate 10 includes: removing the second pattern transfer layer 40, and flattening the top surface of the first pattern transfer layer 30 away from the substrate 10.

Specifically, the second pattern transfer layer 40 may be removed by means of chemical mechanical polishing (CMP), and the top surface of the first pattern transfer layer 30 away from the substrate 10 may be flattened. The flattening is performed by means of CMP, so the manufacturing is simple and the top surface of the processed first pattern transfer layer 30 is relatively flat.

Continuing to refer to FIGS. 2 to 6, an embodiment of the present application further provides a semiconductor structure, which is manufactured by the method for manufacturing a semiconductor structure in the foregoing embodiment.

The semiconductor structure may be a capacitor structure in a dynamic random access memory, the dynamic random access memory further includes a transistor structure connected to the capacitor structure, and the transistor structure may read data stored in the capacitor structure, or the transistor structure may write data into the capacitor structure.

According to the semiconductor structure provided in this embodiment, during manufacturing, a film structure 20 is formed on a substrate 10, the film structure 20 includes a dielectric layer 202, a pattern transfer layer is formed on the film structure 20, a plurality of holes 301 are defined on the pattern transfer layer, and the pattern transfer layer is flattened; then the film structure 20 is etched through the holes 301 to form capacitor holes 206 in the film structure 20; before the capacitor holes 206 are formed, the top surface of the pattern transfer layer is flattened, and the flat top surface of the pattern transfer layer can avoid ion scattering during the etching, thereby avoiding bulging on side walls of the formed capacitor holes 206 or tilting of the capacitor holes 206, improving the dimensional accuracy of the capacitor holes 206 and improving the performance of capacitor structure.

Finally, it should be noted that the above embodiments are merely intended to describe, but not to limit, the technical solutions of the present application. Although the present application is described in detail with reference to the above embodiments, those of ordinary skill in the art should understand that various modifications may be made to the technical solutions described in the foregoing embodiments or equivalent substitutions may be made to some or all technical features thereof, and these modifications or substitutions do not make the essences of the corresponding technical solutions depart from the scope of the technical solutions of the embodiments of the present application.

1. A method for manufacturing a semiconductor structure, comprising:
providing a substrate;
forming a film structure on the substrate, the film structure comprising a dielectric layer;
forming a pattern transfer layer on the film structure, a plurality of holes being defined on the pattern transfer layer;
flattening a top surface of the pattern transfer layer away from the substrate; and
etching the film structure through the holes to form capacitor holes in the film structure.

2. The method for manufacturing the semiconductor structure according to claim 1, wherein the forming a pattern transfer layer on the film structure, a plurality of holes being defined on the pattern transfer layer comprises:
sequentially stacking a first pattern transfer layer and a second pattern transfer layer on the film structure, the second pattern transfer layer having hole patterns; and
transferring the hole patterns to the first pattern transfer layer, to form the holes.

3. The method for manufacturing the semiconductor structure according to claim 2, wherein the flattening a top surface of the pattern transfer layer away from the substrate comprises:
removing the second pattern transfer layer, and flattening a top surface of the first pattern transfer layer away from the substrate.

4. The method for manufacturing the semiconductor structure according to claim 3, wherein the removing the second pattern transfer layer, and flattening a top surface of the first pattern transfer layer away from the substrate comprises:
removing the second pattern transfer layer by a chemical mechanical polishing method, and flattening the top surface of the first pattern transfer layer away from the substrate.

5. The method for manufacturing the semiconductor structure according to claim 2, wherein the first pattern transfer layer is a polysilicon layer, and the second pattern transfer layer is an oxide layer.

6. The method for manufacturing the semiconductor structure according to claim 2, wherein the sequentially stacking a first pattern transfer layer and a second pattern transfer layer on the film structure, the second pattern transfer layer having hole patterns comprises:
etching the second pattern transfer layer to form preset holes, the preset holes extending into the first pattern transfer layer.

7. The method for manufacturing the semiconductor structure according to claim 2, wherein the transferring the hole patterns to the first pattern transfer layer, to form the holes further comprises:
the holes extending into the film structure.

8. The method for manufacturing the semiconductor structure according to claim 1, wherein the forming a film structure on the substrate, the film structure comprising a dielectric layer comprises:
sequentially stacking the dielectric layer and a top film on the substrate.

9. The method for manufacturing the semiconductor structure according to claim 8, wherein the dielectric layer comprises: a first dielectric layer, a middle film and a second dielectric layer sequentially stacked on the substrate.

10. The method for manufacturing the semiconductor structure according to claim 9, wherein materials of the middle film and the top film are the same.

11. The method for manufacturing the semiconductor structure according to claim 10, wherein both the middle film and the top film are titanium nitride layers.

12. The method for manufacturing the semiconductor structure according to claim 9, wherein materials of the first dielectric layer and the second dielectric layer are the same.

13. The method for manufacturing the semiconductor structure according to claim 12, wherein both the first dielectric layer and the second dielectric layer are oxide layers.

14. The method for manufacturing the semiconductor structure according to claim 1, wherein the etching the film structure through the holes to form capacitor holes in the film structure comprises:
etching the film structure through the holes by dry etching to form the capacitor holes in the film structure.

15. A semiconductor structure, manufactured with the method for manufacturing the semiconductor structure according to claim 1.
